(19) United States
(12) Patent Application Publication
(10) Pub. No.: US 2010/0166979 A1
(43) Pub. Date: Jul. 1, 2010

(54) Deposition Apparatus and Substrate Manufacturing Method

(75) Inventor: Takayuki Moriwaki, Hino-shi (JP)

Correspondence Address: BUCHANAN, INGERSOLL & ROONEY PC, POST OFFICE BOX 1404, ALEXANDRIA, VA, 22313-1404, US

(73) Assignee: CANON ANELVA CORPORATION, Kawasaki-shi (JP)

(21) Appl. No.: 12/639,257

(22) Filed: Dec. 16, 2009

(30) Foreign Application Priority Data
Dec. 25, 2008 (JP) 2008-330215
Dec. 1, 2009 (JP) 2009-273988

(51) Int. Cl. C23C 16/52; C23C 16/00; C23C 16/48

(52) U.S. Cl. 427/569; 118/663

(57) ABSTRACT

A deposition apparatus includes a vacuum chamber, a plasma gun adapted to emit a plasma onto a deposition material accommodated in the vacuum chamber, and a discharge gas supply unit adapted to supply a discharge gas to the plasma gun. The deposition apparatus comprises a mass flow controller adapted to change a flow rate of the discharge gas, and a control circuit which is connected to the mass flow controller and adapted to control, the change in flow rate by the mass flow controller, based on a predetermined setting.

### BACKGROUND OF THE INVENTION

1. Field of the Invention

The present invention relates to a deposition apparatus and substrate manufacturing method which use a plasma gun.

2. Description of the Related Art

In recent years, a strong demand has arisen for the mass production of display devices using large substrates for displays such as a liquid crystal display device (to be occasionally abbreviated as an “LCD” hereinafter) and a plasma display device (to be occasionally abbreviated as a “PDP” hereinafter).

Especially in order to increase the production volume of display devices and attain high-resolution panels, an ion plating method which uses a plasma gun is attracting a great deal of attention in forming a thin film made of, for example, MgO (magnesium oxide) as a front-plate electrode protective layer in the structure of a PDP (see Japanese Patent Laid-Open No. 11-269636).

A conventional plasma deposition apparatus used in this ion plating method will be explained below with reference to FIG. 10.

Referring to FIG. 10, a UR plasma gun 9 includes a hollow cathode 1, two intermediate electrodes (a first intermediate electrode 2 and second intermediate electrode 3), for example, to produce a given potential gradient and pressure gradient, and a reflected electron return electrode 4 serving as an anode. The plasma gun 9 is introduced with Ar gas to generate a high-density cylindrical plasma. At this time, the reflected electron return electrode 4 is grounded at a potential higher than that of the hollow cathode 1. Although two intermediate electrodes are used in the example shown in FIG. 10, one or three or more intermediate electrodes may be used.

A cylindrical plasma beam (not shown) formed by the plasma gun 9 may be drawn by a convergence coil 6 into a vacuum chamber 13 which serves as a deposition chamber and includes an exhaust system, and may then be deformed into a sheet shape by permanent magnets (not shown) with their identical poles facing each other. Note that, except for the vacuum chamber 13, the above-mentioned constituent components of the vacuum deposition apparatus constitute a plasma generation device.

A plasma beam 7 deformed into a sheet shape is guided onto the surface of a deposition material 22 along the magnetic lines of force of an attracting magnet 21 located below an evaporation material tray 23 inside the vacuum chamber 13.

The reflected electron return electrode 4 having, at its central portion, a through hole 4a which passes the plasma beam 7 is inserted in a short pipe portion 12 that is a portion in which the vacuum chamber 13 partially projects toward the plasma gun 9. The short pipe portion 12 is located at the exit of the plasma gun 9, that is, coaxially with the plasma beam 7. Moreover, the through hole 4a, which passes the plasma beam 7, in the reflected electron return electrode 4 is surrounded by an insulating tube 5 as an expendable part to insulate the reflected electron return electrode 4 so as to prevent the plasma beam 7 from directly entering the reflected electron return electrode 4.

That is, the plasma beam 7 coming from the hollow cathode 1 of the plasma gun 9 into the vacuum chamber 13 passes through the through hole 4a in the reflected electron return electrode 4, and the insulating tube 5 surrounds the plasma beam 7.

Also, the plasma beam 7 emitted by the plasma gun 9 irradiates the surface of the deposition material 22 upon being guided by a magnetic field. Secondary electrons emitted by the deposition material 22 impinge on the reflected electron return electrode 4 serving as an anode and return to the power supply upon being guided so that they flow back to the same magnetic field.

At this time, all of a protecting plate 11 and other members which cover the interior of a vacuum deposition apparatus 10 have electrically floating potentials so that the electrons reliably return to the reflected electron return electrode 4. The foregoing arrangements solve the above-mentioned problems and therefore deposition can be continued on the surface of a substrate 20 while preventing unipolar charges alone from building up on the material surface.

Particles that evaporate from the surface of the deposition material 22 are ionized at a very high probability. Some of these particles impinge on the reflected electron return electrode 4 upon being guided to the magnetic field formed in the vacuum deposition apparatus 10, like the electrons. Hence, an insulating film containing the deposition material is formed on the surface of the reflected electron return electrode 4. However, ions of, for example, Ar present in the vacuum deposition apparatus 10 sputter the insulating film so as to ensure the return route on the surface of the reflected electron return electrode 4.

Also, to prolong the endurance time of the plasma gun 9, an invention that relates to a pressure gradient type plasma gun is disclosed (see Japanese Patent Laid-Open No. 2001-143895). In this plasma gun, members made of a material having resistance to sputtering are exchangeably attached to the front portions of the first intermediate electrode and second intermediate electrode.

To increase the production volume of PDPs, a high deposition rate (a large thickness of deposition per unit time) is required. Unfortunately, the above-mentioned conventional plasma deposition apparatus poses a problem that the discharge impedance of the plasma gun decreases with time, and the deposition rate, in turn, lowers. Under the circumstance, to prevent a decrease in deposition rate, it is necessary to increase power input to the plasma gun with time. However, any attempt to meet this requirement results in a vicious circle in which the consumption or erosion rates of members in portions through which the plasma passes in the plasma gun accelerate, and the discharge impedance decreases with increasing consumption rate of those members.

With respect to this problem, the inventors of the present invention speculated that the discharge impedance of the plasma gun decreases with time due to the fact that the inner diameters of the electrodes at their central portions through which the plasma passes widen due to consumption of expendable parts of members in portions through which the plasma passes in the plasma gun. The expendable parts herein mean, for example, insulating tubes set at the central portions, through which the plasma passes, of the first intermediate electrode, second intermediate electrode, and return electrode. Despite this fact, even when members of the electrodes at their central portions in the plasma gun have resistance to sputtering, it is difficult to suppress a decrease in discharge impedance with time, as described in Japanese Patent Laid-Open No. 2001-143895.

### SUMMARY OF THE INVENTION

The present invention provides a deposition apparatus and substrate manufacturing method which can deposit films to have the same thickness free from any increase with time in power input to a plasma gun during its continues operation.

According to one aspect of the present invention, there is provided a deposition apparatus including a vacuum chamber, a plasma gun adapted to emit a plasma onto a deposition material accommodated in the vacuum chamber, and a discharge gas supply unit adapted to supply a discharge gas to the plasma gun, comprising:

a mass flow controller adapted to change a flow rate of the discharge gas; and

a control circuit which is connected to the mass flow controller and adapted to control, the change in flow rate by the mass flow controller, based on a predetermined setting.

According to another aspect of the present invention, there is provided a method of manufacturing a substrate on which a deposition material placed in a vacuum chamber is deposited by irradiating the deposition material with a plasma emitted by a plasma gun supplied with a discharge gas, comprising a step of changing a flow rate of the discharge gas supplied to the plasma gun during the deposition of the deposition material.

According to the present invention, it is possible to deposit films to have the same thickness free from any increase with time in power input to a plasma gun. This, in turn, makes it possible to suppress consumption of expendable parts inside the plasma gun, thus prolonging the life of the plasma gun.

Further features of the present invention will become apparent from the following description of exemplary embodiments with reference to the attached drawings.

### BRIEF DESCRIPTION OF THE DRAWINGS

FIG. 1 is a schematic longitudinal sectional view of one embodiment of an ion plating apparatus as a deposition apparatus according to the present invention;

FIG. 2 is a schematic sectional view of another embodiment of an ion plating apparatus as a deposition apparatus according to the present invention;

FIG. 3 is a graph showing the relationship between the discharge argon gas flow rate and the discharge impedance (power: constant);

FIG. 4 is a graph showing a shift in discharge impedance when the discharge argon is reduced by 2 sccm per predetermined operating time of 80 hrs;

FIG. 5 is a graph showing a Comparative Example corresponding to the case shown in FIG. 4 when the discharge Ar flow rate stays constant;

FIG. 6 is a graph showing a shift in power when the discharge argon is reduced by 2 sccm per predetermined operating time of 80 hrs;

FIG. 7 is a graph showing a Comparative Example corresponding to the case shown in FIG. 6 when the discharge Ar flow rate stays constant;

FIG. 8 is a schematic graph showing impedance control by discharge argon flow control during continuous operation;

FIG. 9 is a schematic view showing a shift in power in the execution of impedance control by discharge argon flow control during continuous operation; and

FIG. 10 is a schematic sectional view of an ion plating apparatus as a conventional deposition apparatus.

### DESCRIPTION OF THE EMBODIMENTS

Best modes for carrying out the present invention will be described in detail below with reference to the accompanying drawings.

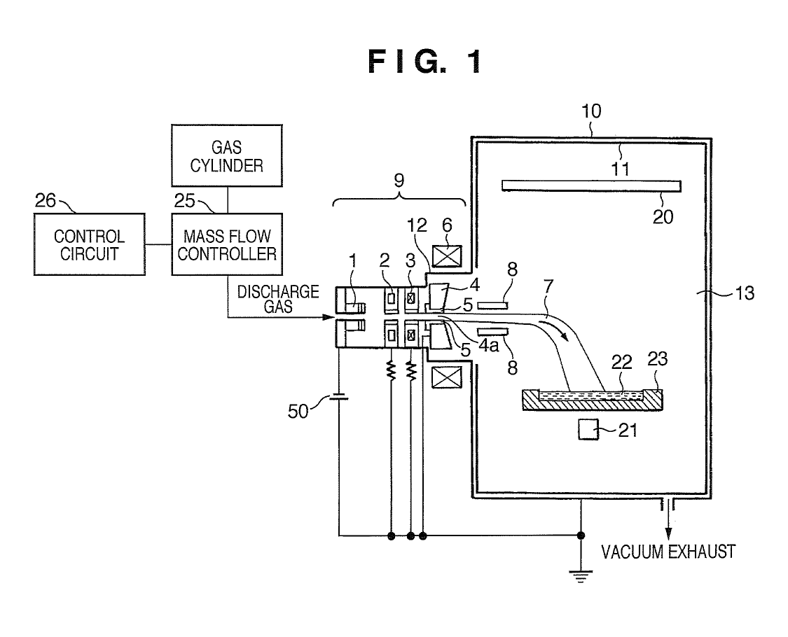

An embodiment of a deposition apparatus according to the present invention will be explained first with reference to FIG. 1.

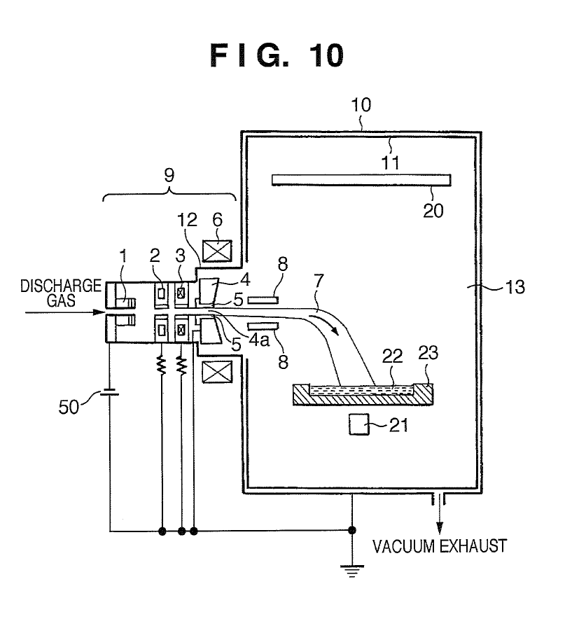

The arrangement of the deposition apparatus according to this embodiment is basically the same as that of the above-described deposition apparatus shown in FIG. 10, and only an overview thereof will be given. A vacuum deposition apparatus 10 includes a plasma gun 9 and vacuum chamber 13. The plasma gun 9 includes a hollow cathode 1, two intermediate electrodes (a first intermediate electrode 2 and second intermediate electrode 3), for example, to produce a given potential gradient and pressure gradient, and a reflected electron return electrode 4 serving as an anode. The number of intermediate electrodes is not limited two, and may be one or three or more. The vacuum chamber 13 includes an evaporation material tray 23, an attracting magnet 21, a substrate 20 for deposition, and a deposition material 22 placed in the tray 23.

A plasma beam formed by the plasma gun 9 is drawn by a convergence coil 6 into the vacuum chamber 13 which serves as a deposition chamber and includes an exhaust system. The reflected electron return electrode 4 having, at its central portion, a through hole 4a which passes a plasma beam 7 is inserted in a short pipe portion 12 that is a portion in which the vacuum chamber 13 partially projects toward the plasma gun 9. The short pipe portion 12 is located at the exit of the plasma gun 9, that is, coaxially with the plasma beam 7. Moreover, the through hole 4a, which passes the plasma beam 7, in the reflected electron return electrode 4 is surrounded by an insulating tube 5 as an expendable part to insulate the reflected electron return electrode 4 so as to prevent the plasma beam 7 from directly entering the reflected electron return electrode 4.

It is also possible to employ a deposition apparatus which uses a plasma gun having an arrangement other than the above-mentioned one.

The feature of this embodiment lies in a mass flow controller 25 set in a discharge gas supply unit which supplies a discharge gas from a gas cylinder to the plasma gun, that is, a discharge gas supply route, as shown in FIG. 1. The mass flow controller 25 can change the flow rate of the discharge gas to be supplied. Further, the mass flow controller 25 is connected to a control circuit 26 which controls, the change in flow rate of the discharge gas, based on a predetermined setting. The control circuit 26 is installed with a program for changing the gas flow rate. The mass flow controller 25 can change the gas flow rate in accordance with the signal from the control circuit 26. The discharge gas is not limited to Ar (argon), and may be another inert gas such as He (helium).

The vacuum chamber 13 moreover includes a unit which can successively transport substrates 20 and therefore can successively perform deposition. This is a moving deposition scheme in which substrates undergo deposition while successively passing through the upper side of the deposition material that evaporates upon being irradiated with a plasma. This allows the mass production of substrates having films deposited on them, unlike a method of processing stationary substrates one by one.

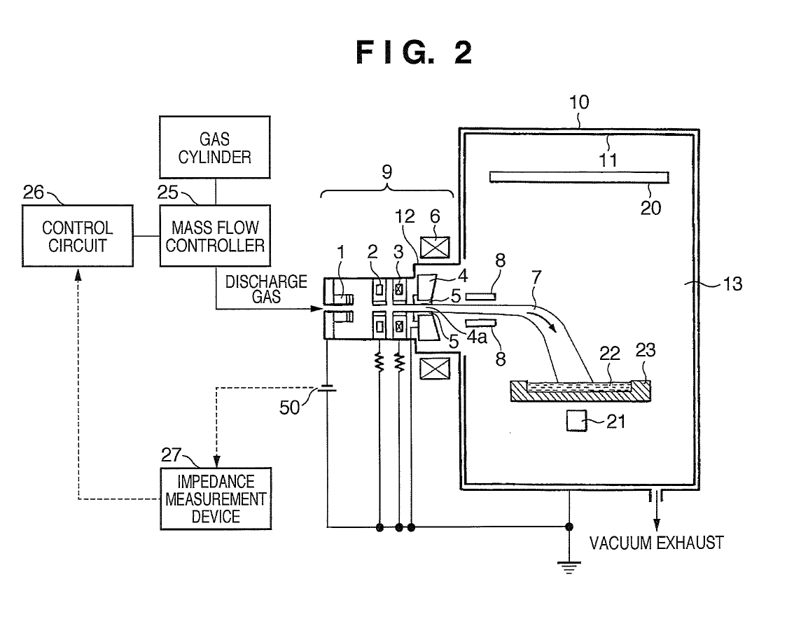

FIG. 2 shows another embodiment of a deposition apparatus according to the present invention. In addition to the constituent elements of the deposition apparatus shown in FIG. 1, the deposition apparatus shown in FIG. 2 includes an impedance measurement device 27 which sends data to the control circuit 26. The impedance measurement device 27 measures a voltage and current flowing through the plasma gun and computes the discharge impedance based on the measurement results. Data on the discharge impedance measured by the impedance measurement device 27 is sent to the control circuit 26 to control the Ar gas flow rate by the program installed in the control circuit 26 in advance.

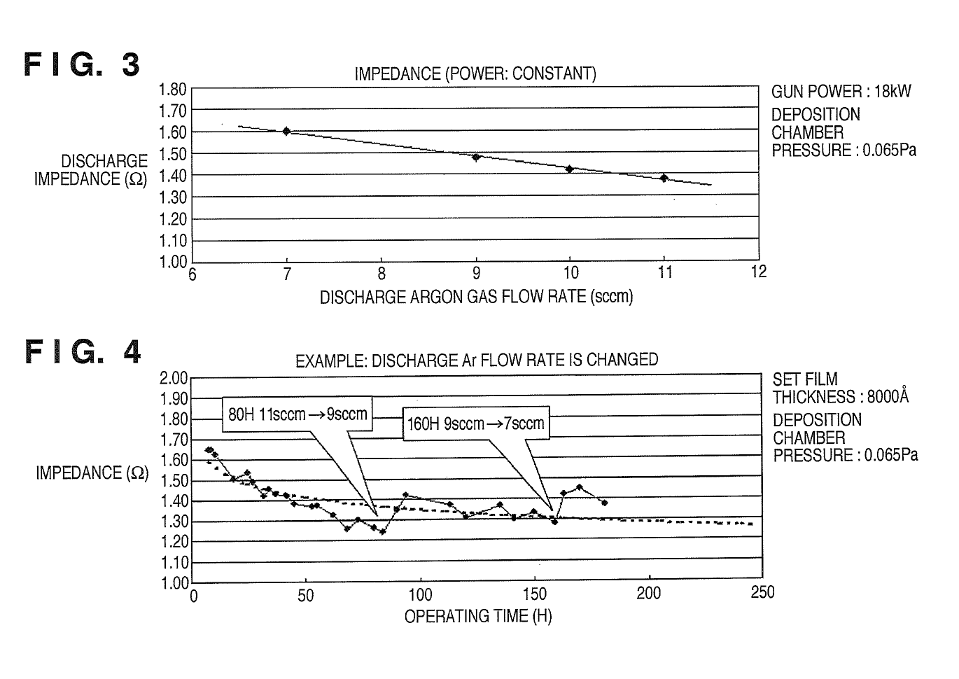

Note that the flow rate of a discharge gas introduced into the plasma gun and the discharge impedance have a correlation between them. FIG. 3 shows the measurement result of the relationship between the discharge Ar gas flow rate and the discharge impedance while power supplied to the plasma gun stays constant. When the amount of power supplied to the plasma gun stays constant, the discharge impedance increases as the Ar gas flow rate lowers for the following reason.

Discharge takes place upon applying a voltage to a gas space under a vacuum. The discharge voltage at this time is known to depend on the gas pressure in the gas space. The discharge voltage rises as the gas pressure drops in the pressure region of a plasma deposition process such as an ion plating method or a sputtering method. The plasma gun generates a plasma by discharge on the cathode inside it. Hence, as the discharge Ar flow rate lowers, the pressure in the plasma gun drops and so the discharge voltage (impedance) rises.

In view of this, when an MgO film, for example, is formed on the substrate upon reducing discharge Ar gas introduced into the plasma gun, it is possible to increase the discharge impedance of the generated plasma. Note that the Ar gas flow rate is measured by the mass flow controller 25. The discharge impedance can be measured from a current value and voltage value of a DC power supply, which are sufficient to generate a plasma.

Conventionally, a decrease in discharge impedance with time poses the following problem. As the discharge impedance decreases, the deposition rate, in turn, lowers. Therefore, it is necessary to increase the amount of power input to the plasma gun in that case. This is because, as the impedance decreases when the amount of power stays constant, the current rises and the voltage drops. Since electrons present in a plasma are supplied with energy upon being accelerated in proportion to the voltage, a drop in voltage leads to a reduction in energy of the electrons present in the plasma. In other words, as the discharge impedance decreases, the electron energy in the plasma applied to, for example, an MgO material reduces, and the evaporation rate of this material, in turn, lowers. From this viewpoint, conventionally, the amount of power input to the plasma gun is increased with time in order to prevent a decrease in discharge impedance with time. However, this method raises the cost involved in an increase in amount of power consumption.

In contrast to this, the present invention prevents a decrease in discharge impedance with time by controlling the amount of discharge gas introduced into the plasma gun, as has been described above. That is, a conventional deposition method copes with the above-mentioned problem by largely increasing the amount of power input to the plasma gun while the amount of discharge gas introduced into the plasma gun stays constant during apparatus operation, whereas the present invention can solve the above-mentioned problem while suppressing an increase in amount of power by reducing the amount of discharge gas introduced into the plasma gun during apparatus operation.

In the embodiment of the present invention, the amount of discharge gas introduced into the plasma gun is decreased in the following way.

(1) Method of Decreasing Amount of Discharge Gas with Time

This method has an approach which gradually lowers the gas flow rate per preset time, and an approach which continuously lowers the gas flow rate. From the viewpoint of facilitating control of the mass flow controller, the former approach which lowers the gas flow rate per preset time is preferable. A decrease in discharge impedance with time can be appropriately corrected as long as the predetermined time interval is set to 80 hrs or less. When Ar, for example, is used as the discharge gas, a decrease in discharge impedance with time can be appropriately corrected as long as the Ar gas flow rate is lowered by 2 to 3 sccm per 80 hrs.

Because this method performs control with low accuracy, it narrows the range of fluctuation in film thickness but does not sufficiently uniform each film thickness. Under the circumstance, a fluctuation in film thickness with time can be further reduced by periodically measuring the film thicknesses and performing power correction in accordance with the measurement results.

(2) Case in which Gas Flow Rate is Lowered so as to Maintain Discharge Impedance Constant

This method lowers the gas flow rate when the measured impedance value is less than a preset impedance value, and raises it when the measured impedance value is more than the preset impedance value. A control device installed with a program for controlling the gas flow rate in the foregoing way is disposed and sends a signal to the mass flow controller to control it. The control is performed so that the control response characteristic preferably falls within the range of ±0.015Ω for the set impedance by optimizing the program in the control device. This makes it possible to control the film thickness with high accuracy without increasing the input power with time.

Note that stable discharge is impossible when the discharge gas flow rate becomes too low upon being lowered in order to prevent a decrease in impedance. Hence, when Ar is used as the discharge gas, the Ar flow rate is preferably 5 sccm or more for the following reason. Through the measurement of the pressure in the plasma gun (cathode), the inventors of the present invention found that the characteristic of a change in pressure in response to a change in flow rate changes at an Ar flow rate threshold of 5 sccm. A change in pressure in response to a change in flow rate is relatively small at a flow rate of 5 sccm or more, whereas that change is relatively large at a flow rate less than 5 sccm. This reveals that stable discharge is possible as long as the Ar flow rate is 5 sccm or more. The reason for this is expected to be that, when the Ar flow rate is 5 sccm or more, Ar atoms are present in the intermediate flow region at the boundary between a viscous flow region where the mean free path of Ar atoms is short enough to ignore relative to the internal dimension of the gun and a molecular flow region where the mean free path of Ar atoms is long relative to the internal dimension of the gun. That is, in the intermediate flow region, gas molecules collide with each other and so are mainly exhausted with a continuous flow distribution, thus suppressing a change in pressure in the plasma gun attributed to the consumption state of internal parts.

Examples of the present invention will be described in detail below, but the present invention is not limited to them.

### Example 1

In this Example, an MgO film was deposited on a glass substrate using a deposition apparatus according to the embodiment shown in FIG. 1. Note that the deposition apparatus was introduced with oxygen and argon from a gas inlet pipe (not shown).

FIG. 4 shows the relationship between the operating time and the discharge impedance when the deposition apparatus is continuously operated while the discharge Ar gas flow rate is lowered by 2 sccm per predetermined operating time (per 80 hrs in this case). Also, FIG. 6 shows the relationship between the operating time and the amount of power supplied to a plasma gun.

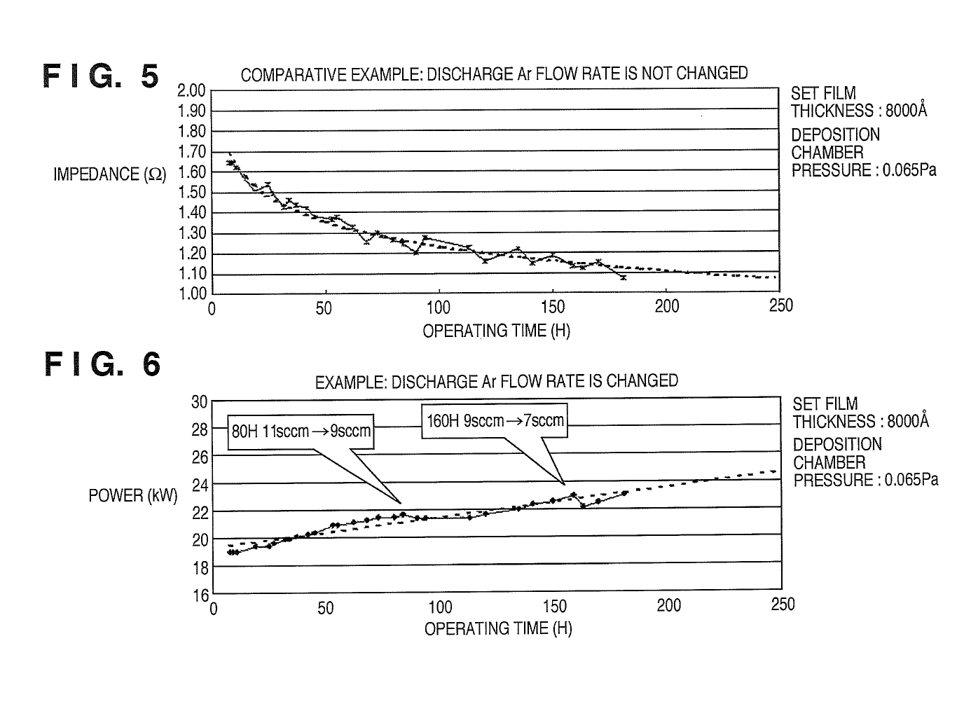

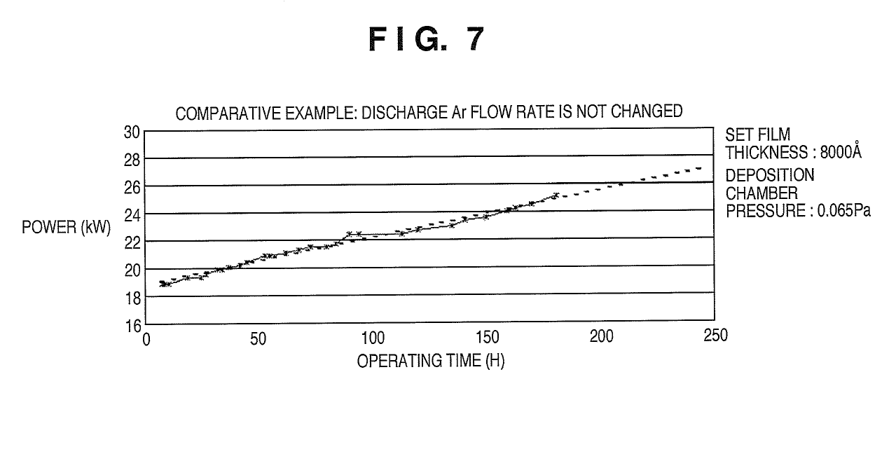

FIGS. 5 and 7 show the corresponding relationships when the discharge Ar gas flow rate stays constant (prior art) as Comparative Examples. As can be seen from FIGS. 5 and 7, to suppress a decrease in impedance when the Ar flow rate is not controlled as in the prior art, it is necessary to continue considerably increasing the amount of power supplied to the plasma gun. Worse still, a decrease in impedance cannot be greatly suppressed even by increasing the amount of power, again as can bee seen from FIGS. 5 and 7.

In contrast to this, as can be seen from FIGS. 4 and 6, a decrease in discharge impedance with time can be drastically suppressed by periodically changing the discharge argon gas flow rate during continuous operation as in the Example of the present invention, thus greatly suppressing an increase in power supplied to the plasma gun (attaining low power consumption). This makes it possible to suppress consumption of expendable parts inside the plasma gun and therefore to prolong the life of the plasma gun.

### Example 2

In this Example, an MgO film was deposited on a glass substrate using a deposition apparatus according to the embodiment shown in FIG. 2. Note that the deposition apparatus was introduced with oxygen and argon from a gas inlet pipe (not shown).

In this Example, instead of periodically changing the discharge Ar flow rate as in Example 1, the flow rate of Ar gas introduced into a plasma gun so that the discharge impedance stays constant was controlled. That is, an impedance measurement device 27 shown in FIG. 2 always measured the discharge impedances and sent the obtained measurement data to a control circuit 26. Then, if the discharge impedance value was less than a preset value (1.6Ω in this case), the control circuit 26 sent a signal to a mass flow controller to decrease the value of the Ar gas flow rate.

In this Example, the gas flow rate was controlled in the following way. If the measured discharge impedance decreased by less than 0.015Ω from the initial value of the discharge impedance (1.6Ω in this case), the gas flow rate was not changed. If the measured discharge impedance decreased by 0.015Ω or more from that initial value, the gas flow rate started being controlled so that the discharge impedance becomes nearly constant (within an allowance of ±0.015Ω). The initial value of the discharge impedance is preferably 1.50 or more to 2.0Ω or less.

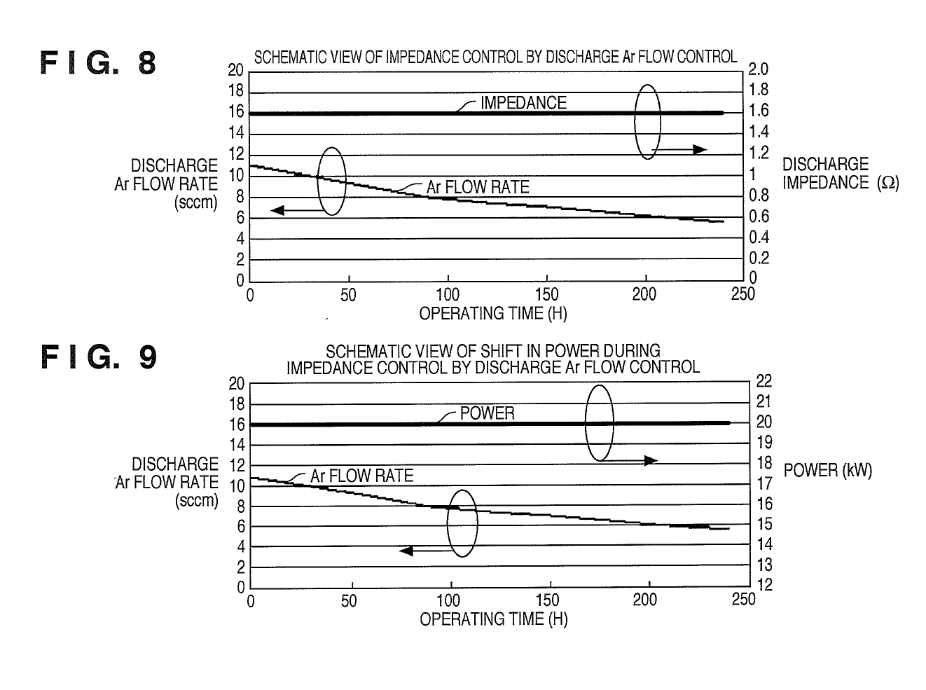

FIGS. 8 and 9 are a graph schematically showing impedance control by discharge argon flow control during continuous operation and a graph schematically showing a shift in power under this control when the above-mentioned control is exploited. As can be seen from FIGS. 8 and 9, the above-mentioned control suppresses both a decrease in impedance and an increase in power during continuous operation. This makes it possible to suppress consumption of expendable parts inside the plasma gun and therefore to prolong the life of the plasma gun.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2008-330215, filed Dec. 25, 2008, and No. 2009-273988 filed Dec. 1, 2009, which are hereby incorporated by reference herein in their entirety.

What is claimed is:

1. A deposition apparatus including a vacuum chamber, a plasma gun adapted to emit a plasma onto a deposition material accommodated in the vacuum chamber, and a discharge gas supply unit adapted to supply a discharge gas to the plasma gun, comprising:
a mass flow controller adapted to change a flow rate of the discharge gas; and
a control circuit which is connected to said mass flow controller and adapted to control, the change in flow rate by said mass flow controller, based on a predetermined setting.

2. The apparatus according to claim 1, further comprising:
a discharge impedance measurement unit adapted to measure a discharge impedance of the plasma gun,
wherein said discharge impedance measurement unit is connected to said control circuit and changes the flow rate of the discharge gas based on the discharge impedance measurement result.

3. A method of manufacturing a substrate on which a deposition material placed in a vacuum chamber is deposited by irradiating the deposition material with a plasma emitted by a plasma gun supplied with a discharge gas, comprising a step of:
changing a flow rate of the discharge gas supplied to the plasma gun during the deposition of the deposition material.

4. The method according to claim 3, wherein
in the changing step, the flow rate of the discharge gas is gradually lowered per preset time.

5. The method according to claim 3, wherein
in the changing step, the flow rate of the discharge gas is lowered continuously.

6. The method according to claim 3, wherein
in the changing step, the flow rate of the discharge gas is lowered if a measured discharge impedance value is lower than a preset discharge impedance value, and the flow rate of the discharge gas is raised if the measured discharge impedance value is higher than the preset discharge impedance value.
